(19) United States
(12) Patent Application Publication
(10) Pub. No.: US 2006/0098498 A1
(43) Pub. Date: May 11, 2006

(54) Methods of reading data including comparing multiple measurements of a characteristic of a data storage element and related devices

(76) Inventors: Won-Cheol Jeong, Seoul (KR); Jae-Hyun Park, Gyeonggi-do (KR)

Correspondence Address: MYERS BIGEL SIBLEY & SAJOVEC, PO BOX 37428, RALEIGH, NC, 27627, US

(21) Appl. No.: 11/241,605

(22) Filed: Sep. 30, 2005

(30) Foreign Application Priority Data
Oct. 26, 2004 (KR) 2004-85752

(51) Int. Cl. G11C 7/06

(52) U.S. Cl. 365/189.07

(57) ABSTRACT

A method of reading data stored in a data storage element of an integrated circuit memory device may include applying a first electrical signal to the data storage element, and while applying the first electrical signal, taking a first measurement of an electrical characteristic of the data storage element. After taking the first measurement of the electrical characteristic, a second electrical signal may be applied to the data storage element with the first and second electrical signals being different. While applying the second electrical signal, a second measurement of the electrical characteristic of the data storage element may be taken, and the first and second measurements of the electrical characteristic of the data storage element may be compared to determine a state of the data stored in the data storage element. Related devices are also discussed.

### RELATED APPLICATION

This application claims the benefit of priority from Korean Patent Application No. 2004-85752, filed on Oct. 26, 2004 in the Korean Intellectual Property Office, the disclosure of which is hereby incorporated herein in its entirety by reference.

### FIELD OF THE INVENTION

The present invention relates to semiconductor devices and, more particularly, to semiconductor memory devices and related methods.

### BACKGROUND

With advances in electronics industries such as the mobile telecommunications and computer industries, there are increasing demands for semiconductor memory devices having additional functionalities and improved performance. Currently available memory devices (e.g., SRAMs, DRAMs, flash memories, FRAMs, etc.), however, may not meet these demands. These currently available memory devices have advantages and disadvantages that will discussed with reference to the following table [Table 1]. Accordingly, currently available memory devices may not meet all characteristics that electronic devices may demand.

TABLE 1

| | SRAM | DRAM | FLASH | FRAM | MRAM |
|---|---|---|---|---|---|
| Read | H | M | H | M | M-H |
| Write | H | M | L | M | M-H |
| Non- | No | No | Yes | Neutral | Yes |
| volatility | | | | | |
| Refresh | Unnecessary | Necessary | Un- | Un- | Un- |
| | | | necessary | necessary | necessary |
| Size of | Large | Small | Small | Medium | Small |
| Unit Cell | | | | | |
| Low | Possible | Limited | Impossible | Limited | Possible |
| Voltage | | | | | |
| for | | | | | |
| Operation | | | | | |

*H: high speed, M: medium speed, L: low speed

MRAMs (magnetic random access memories or magnetoresistive random access memories) may provide advantages such as non-volatility, unlimited reusability, high integration, high operating speed, and/or low voltage operation. An MRAM has a magnetic tunnel junction that includes a pinning layer, a pinned layer, an insulation layer, and a free layer. A resistance of the magnetic tunnel junction is determined based on magnetization directions of the free layer and the pinned layer. With the resistance characteristic based on the magnetization direction, the magnetic tunnel junction may be used as a data storage element in the MRAM.

An operation of reading data stored in a specific cell of a MRAM may include measuring a resistance of the magnetic tunnel junction and comparing the measured resistance with a reference resistance. According to a manner of selecting the reference resistance, the read operation may be classified as an external reference scheme or a self-reference scheme. The external reference scheme uses the resistance of a predetermined reference device as the reference resistance, while the self-reference scheme uses a self resistance of a different state as the reference resistance (as will be discussed in greater detail below).

A resistance of the magnetic tunnel junction may vary exponentially with respect to a thickness of the insulation layer. Variation of the thickness of the insulation layer may thus need to be maintained within approximately one angstrom to effectively perform a read operation based on the external reference scheme. For this reason, the self-reference scheme is becoming increasingly attractive as an alternative to read MRAMs.

FIG. 1 is a flowchart illustrating a conventional read operation of a magnetic memory using a self-reference scheme.

As illustrated in FIG. 1, an initial resistance Rᵢ of a magnetic tunnel junction is measured at block S1. The resistance Rᵢ corresponds to initial data written to the magnetic tunnel junction. A first write operation is performed to write predetermined data into the magnetic tunnel junction at block S2. A final resistance R_{f} of the magnetic tunnel junction is measured at block S3. The initial resistance Rᵢ and the final resistance R_{f} are compared with each other at block S4.

If the initial data of the magnetic tunnel junction is identical to the final data written by the performing first write operation at block S2, a difference of the initial resistance Rᵢ and the final resistance R_{f} (R_{f}−Rᵢ) is smaller than a threshold value. If the initial and final data are different from each other, the difference of the initial resistance Rᵢ and the final resistance R_{f} (R_{f}−Rᵢ) is larger than the threshold value. Such a difference is used to read the initial data stored in the magnetic tunnel junction. If the initial data and the final data are different, a second write operation is performed to restore the magnetic tunnel junction to an initial state at block S5.

The above-described read operation based on the self-reference scheme includes at least one writing step. Further, the read operation may include two writing steps if the initial data and the final data are different. Due to the writing step (steps), power consumption of products may increase and battery life may be reduced.

### SUMMARY

According to embodiments of the present invention, methods of reading data stored in a data storage element of an integrated circuit memory device may be provided. For example, a first electrical signal may be applied to the data storage element, and while applying the first electrical signal, a first measurement of an electrical characteristic of the data storage element may be taken. After taking the first measurement of the electrical characteristic, a second electrical signal may be applied to the data storage element with the first and second electrical signals being different. While applying the second electrical signal, a second measurement of the electrical characteristic of the data storage element may be taken, and the first and second measurements of the electrical characteristic of the data storage element may be compared to determine a state of the data stored in the data storage element.

More particularly, the data storage element may include a magnetic tunnel junction (MTJ) structure. The magnetic tunnel junction structure may include a pinning layer, a pinned layer, an insulation layer, and a free layer, with the pinned layer between the pinning layer and the insulation layer, and with the insulation layer between the pinned layer and the free layer. The pinning layer may include an anti-ferromagnetic layer, the pinned layer and the free layer may each include a respective ferromagnetic layer, and the insulation layer may include an aluminum oxide layer.

In addition, applying the first electrical signal may include applying a first voltage across the data storage element, applying the second electrical signal may include applying a second voltage across the data storage element, and the first and second voltages are different. According to some embodiments of the present invention, taking the first measurement of the electrical characteristic may include measuring a first current through the data storage element, and taking the second measurement of the electrical characteristic may include measuring a second current through the data storage element. According to other embodiments of the present invention, taking the first measurement of the electrical characteristic may include measuring a first resistance through the data storage element, and taking the second measurement of the electrical characteristic may include measuring a second resistance through the data storage element.

Moreover, data stored in the data storage element may take one of first and second data states. A difference between the first and second measurements may be below a threshold when data of the first data state is stored in the data storage element, and the difference between the first and second measurements may exceed the threshold when data of the second data state is stored in the data storage element.

According to additional embodiments of the present invention, an integrated circuit memory device may include a data storage element and a controller coupled to the data storage element. The controller may be configured to take a first measurement of an electrical characteristic of the data storage element while applying a first electrical signal to the data storage element, and to take a second measurement of the electrical characteristic of the data storage element while applying a second electrical signal to the data storage element after taking the first measurement. The controller may be further configured to compare the first and second measurements of the electrical characteristic of the data storage element to determine a state of the data stored in the data storage element.

More particularly, the data storage element may include a magnetic tunnel junction (MTJ) structure. The magnetic tunnel junction structure may include a pinning layer, a pinned layer, an insulation layer, and a free layer, with the pinned layer between the pinning layer and the insulation layer, and with the insulation layer between the pinned layer and the free layer. The pinning layer may include an anti-ferromagnetic layer, the pinned layer and the free layer may each include a respective ferromagnetic layer, and the insulation layer may include an aluminum oxide layer.

The controller may be configured to apply the first electrical signal by applying a first voltage across the data storage element, and to apply the second electrical signal by applying a second voltage across the data storage element with the first and second voltages being different. According to some embodiments of the present invention, the controller may be configured to take the first measurement of the electrical characteristic by measuring a first current through the data storage element, and to take the second measurement of the electrical characteristic by measuring a second current through the data storage element. According to other embodiments of the present invention, the controller may be configured to take the first measurement of the electrical characteristic by measuring a first resistance through the data storage element, and to take the second measurement of the electrical characteristic by measuring a second resistance through the data storage element.

In addition, data stored in the data storage element may take one of first and second data states. A difference between the first and second measurements may be below a threshold when data of the first data state is stored in the data storage element, and the difference between the first and second measurements may exceeds the threshold when data of the second data state is stored in the data storage element.

According to some embodiments of the present invention, memory devices may be provided that perform a read operation without a writing step. According to other embodiments of the present invention, a reading scheme may be provided for a memory device wherein data stored therein is sensed without a writing step. According to still other embodiments of the present invention, a reading scheme may be provided for a magnetic memory wherein data stored therein is sensed without a writing step.

According to some embodiments of the present invention, a memory device may be provided where a change of an electrical characteristic varies with voltage fluctuation. The memory device may include a data storage element having a first terminal and a second terminal. The data storage element may store first-state data and second-state data. A change of the electrical characteristic of the data storage element, based on fluctuation of a voltage between the first and second terminals, may vary depending on whether data stored in the data storage element has the first state or the second state.

More particularly, the electrical characteristic may be a voltage-current characteristic and/or a voltage-resistance characteristic.

The data storage element may include an insulation layer between the first and second terminals. The first terminal may include an anti-ferromagnetic layer and a ferromagnetic layer that are stacked with the ferromagnetic layer between the anti-ferromagnetic layer and the insulation layer, and the second terminal may include a ferromagnetic layer. The insulation layer may thus be in contact with the ferromagnetic layers of the first and second terminals. The first state may be defined such that magnetization directions of the ferromagnetic layers of the first and second terminals are parallel and thus a resistance between the first and second terminals is less than a predetermined reference (also referred to as a threshold resistance). The second state may be defined such that the magnetization directions of the ferromagnetic layers of the first and second terminals are antiparallel and thus a resistance between the first and second terminals is greater than the predetermined reference (e.g., the threshold resistance).

According to additional embodiments of the present invention, a read scheme may be provided for a memory device having a first terminal and a second terminal and a data storage element in which first-state or second-state data is stored. The read scheme may include providing a memory device where a change of an electrical characteristic of the data storage element, based on fluctuation of a voltage between the first and second terminals, varies depending on whether data stored in the data storage element is first-state data or second-state data. A first voltage may be applied between the first and second terminals to measure the electrical characteristic of the data storage element. A second voltage may be applied between the first and second terminals to measure the electrical characteristic of the data storage element, the second voltage being different from the first voltage. The measured electrical characteristics may be compared with each other to determine initial data stored in the data storage element without requiring a write operation for data restoration.

The data storage element may have a voltage-current characteristic such that the amount of current flowing between the first and second terminals changes more rapidly where data stored in the data storage element is the second-state data than where the data stored in the data storage element is the first-state data. The voltage-current characteristic of the data storage element may be used to nondestructively read initial data stored in the data storage element.

In an alternative, the data storage element may have a voltage-current characteristic such that a resistance between the first and second terminals, based on fluctuation of a voltage applied therebetween, changes more rapidly where data stored in the data storage element is the second-state data than where the data stored in the data storage element is the first-state data. The voltage-current characteristic of the data storage element may be used to nondestructively read initial data stored in the data storage element.

The first terminal may include an anti-ferromagnetic layer and a ferromagnetic layer, the second terminal may include-a ferromagnetic layer, and an insulation layer may be provided between the first and second terminals. More particularly, the ferromagnetic layer of the first terminal may be provided between the anti-ferromagnetic layer and the insulation layer such that the insulation layer is in contact with the ferromagnetic layers of the first and second terminals. The first and second voltages may be applied to measure tunneling current of the insulation layer determined by a relative magnetization direction between the ferromagnetic layer of the first terminal and the ferromagnetic layer of the second terminal.

### BRIEF DESCRIPTION OF THE DRAWINGS

FIG. 1 is a flowchart illustrating a conventional read operation of a magnetic memory using a self-reference scheme.

FIG. 2 is a graph of a voltage-resistance characteristic of a data storage element according to some embodiments of the present invention.

FIG. 3 is a circuit diagram of a test device used to measure electrical characteristics of data storage elements according to some embodiments of the present invention.

FIGS. 4A to 4C are graphs illustrating variations of electrical characteristics with voltage fluctuations of data storage elements according to some embodiments of the present invention.

FIG. 5 is a circuit diagram illustrating a unit cell of a memory device according to some embodiments of the present invention.

FIGS. 6A and B are respectively a circuit diagram and a top plan view of a portion of a cell array region in a memory device according to some embodiments of the present invention.

FIG. 6C is a cross-sectional view taken along section line I-I′ of FIG. 6B.

FIG. 6D is a perspective view illustrating configurations of a data storage element according to some embodiments of the present invention.

FIG. 7 is a flowchart illustrating read operations of memory devices according to some embodiments of the present invention.

FIG. 8 is a graph illustrating a resistance variation with fluctuation of a voltage applied to a data storage element during a read operation of a memory device according to some embodiments of the present invention.

FIG. 9 is a circuit diagram illustrating a controller coupled to an array of memory cells according to embodiments of the present invention.

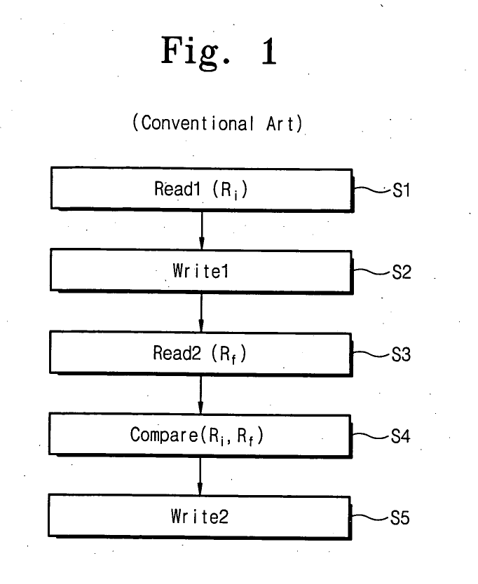

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

In the drawings, thickness and/or widths of layers, regions, and/or lines are exaggerated for clarity. It will also be understood that when an element such as a layer, region or substrate is referred to as being on another element, it can be directly on the other element or intervening elements may also be present. In contrast, if an element such as a layer, region or substrate is referred to as being directly on another element, then no other intervening elements are present. As used herein, the term and/or includes any and all combinations of one or more of the associated listed items.

Furthermore, relative terms, such as beneath, over, under, upper, and/or lower may be used herein to describe one element's relationship to another element as illustrated in the figures. It will be understood that relative terms are intended to encompass different orientations of the device in addition to the orientation depicted in the figures. For example, if the device in one of the figures is turned over, elements described as below other elements would then be oriented above the other elements. The exemplary term below, can therefore, encompasses both an orientation of above and below.

It will be understood that although the terms first and second are used herein to describe various regions, layers and/or sections, these regions, layers and/or sections should not be limited by these terms. These terms are only used to distinguish one region, layer or section from another region, layer or section. Thus, a first region, layer or section discussed below could be termed a second region, layer or section, and similarly, a second region, layer or section could be termed a first region, layer or section without departing from the teachings of the present invention. Like numbers refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

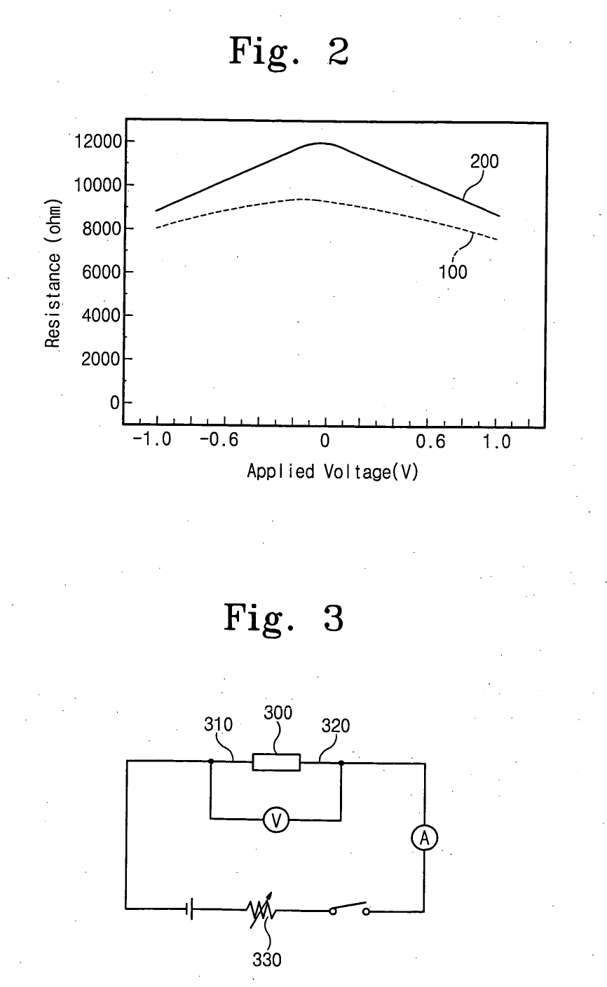

A memory device according to some embodiments of the present invention may include a data storage element having a first terminal and a second terminal. The data storage element may store first-state data or second-state data (e.g., a “1” or a “0”). A change of an electrical characteristic, based on voltage fluctuation of the data storage element, may vary with data stored therein. When a voltage applied between the first and second terminals fluctuates (or changes), the change of the electrical characteristic of the data storage cell may be higher at the first-state data than at the second-state data, as illustrated in FIG. 2.

FIG. 2 illustrates voltage-resistance characteristics of a data storage element according to some embodiments of the present invention. The voltage-resistance characteristics may be measured using a test device such as that illustrated in FIG. 3.

Referring to FIGS. 2 and 3, a current flowing through an ammeter “A” is measured while a voltage applied between a first terminal 310 and a second terminal 320 of the data storage element 300 is changed. The applied voltage may be changed by controlling a variable resistance 330 of the test device illustrated in FIG. 3. Values of the changing voltage may be measured using a voltmeter “V” connected in parallel with the data storage element 300. In the graph of FIG. 2, a horizontal axis indicates a voltage applied between the first terminal 310 and the second terminal 320, and a vertical axis indicates a resistance therebetween. The resistance may be computed based on the voltage and current values measured using the voltmeter “V” and the ammeter “A”.

According to some embodiments of the present invention, the first terminal 310 may include an anti-ferromagnetic layer (including at least one selected from the group consisting of IrMn, PtMn, MnO, MnS, MnTe, MnF₂, FeF₂, FeCl₂, FeO, CoCl₂, CoO, NiCl₂, and/or Cr), and a ferromagnetic layer (including at least one selected from the group consisting of Fe, Co, Ni, Gd, Dy, MnAs, MnBi, MnSb, CrO₂, MnOFe₂O₃, FeOFe₂O₃, CuOFe₂O₃, MgOFe₂O₃, EuO, and/or Y₃Fe₅O₁₂). The second terminal may include a ferromagnetic layer (including at least one selected from the group consisting of Fe, Co, Ni, Gd, Dy, MnAs, MnBi, MnSb, CrO₂, MnOFe₂O₃, FeOFe₂O₃, CuOFe₂O₃, MgOFe₂O₃, EuO, and/or Y₃Fe₅O₁₂). In addition, an insulation layer such as an aluminum oxide layer may be provided between the first terminal 310 and the second terminal 320. The insulation layer may be in contact with the ferromagnetic layer of the first terminal 310 and the ferromagnetic layer of the second terminal 320. The data storage element 300 may be rectangular, such that its length is longer or shorter than its width.

According to the test result, the data storage element 300 may have one of two different states relative to the same applied voltage. Namely, the data storage element 300 may have one of two different resistances, and states of the two resistances may be used to determine a data-state stored in the data storage element 300. Such a voltage-resistance characteristic can thus be used to distinguish data stored in the data storage element.

A read operation of a memory device may be used to determine data stored in a data storage element of the memory device. As discussed above, a sensing method for a read operation may use an external reference scheme or a self-reference scheme. In a magnetic memory device, a read operation using an external reference scheme may have a technical difficulty associated with thickness control of an insulation layer of the data storage element, and a read operation using the self-reference scheme may need a write operation for data restoration.

According to the test result of FIG. 2, a curve 100 indicates a first-state data (e.g., logic “0”) stored in the data storage element 300, and a curve 200 indicates a second-state data (e.g., logic “1”) stored in the data storage element. The curve 100 is more gently inclined than the curve 200 (i.e., slopes of the curve 100 are less than slopes of the curve 200). A read operation of a memory device having such a characteristic may be performed using a self-reference scheme without a write operation for data restoration.

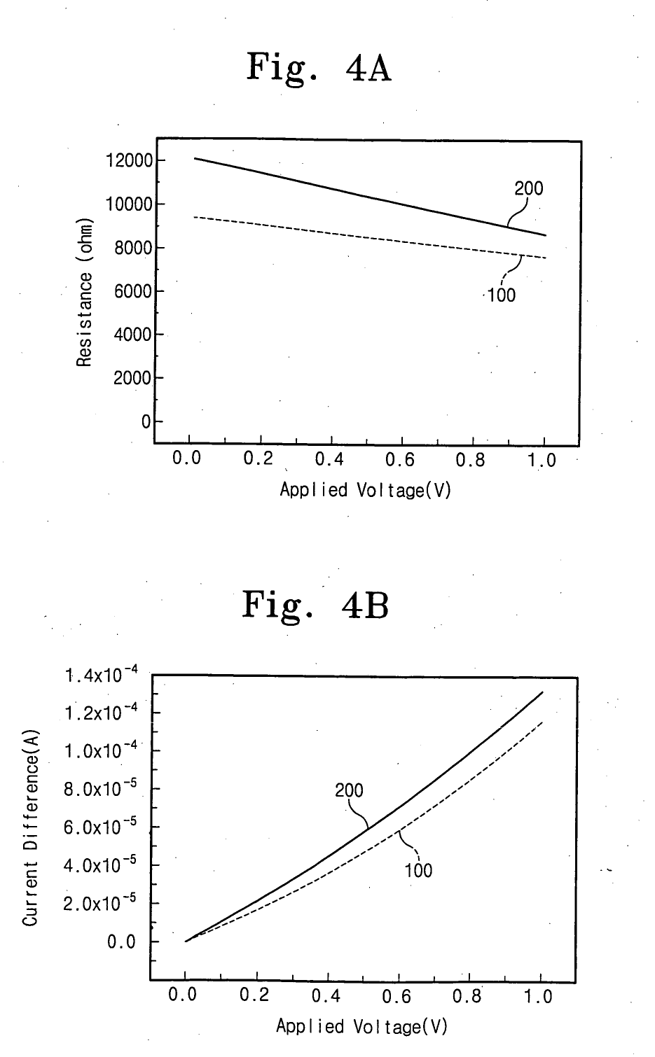

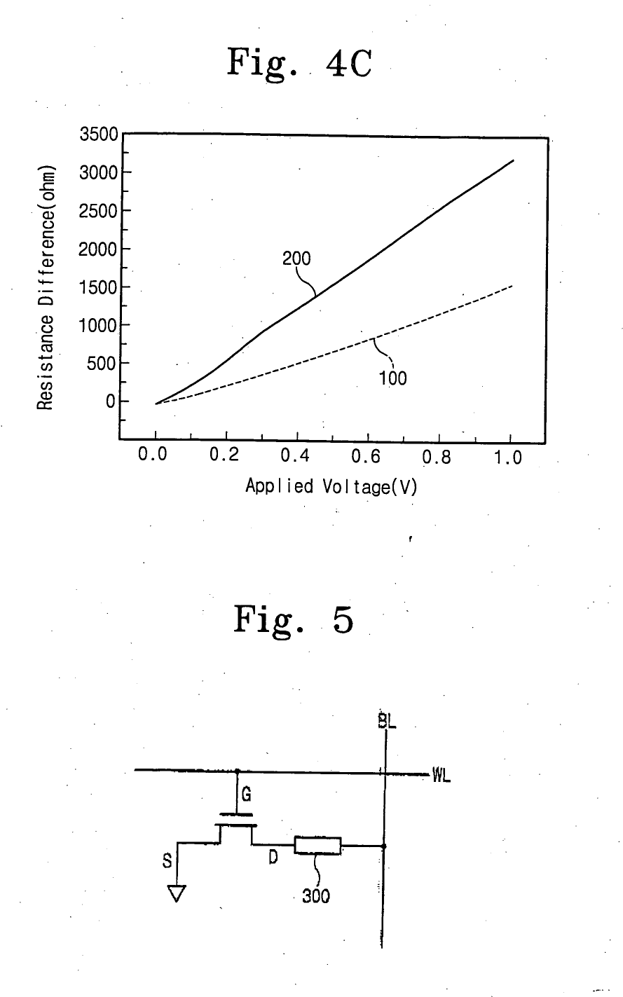

FIG. 4A, FIG. 4B, and FIG. 4C are graphs illustrating read methods performed using a self-reference scheme without a write operation for data restoration. Referring to FIG. 4A, as a voltage applied between the first and second terminals 310 and 320 increases, a resistance of the data storage element 300 may decrease with a slope (or inclination) of −1598 when data of the first-state data is stored, and the resistance may decrease with a slope (or inclination) of −3295 when data of the second-state data is stored.

FIG. 4B illustrates a change of current. When a voltage applied to the data storage element 300 increases from 0.01 volt to 0.06 volt, a change of current flowing through the data storage element 300 is about 5.8×10⁻⁵ ampere when data of the first-state data is stored, and a change of current is about 6.9×10⁻⁵ when data of the second-state data is stored. A difference of current magnitudes between the first-state data and the second-state data may thus be about 1.1×10⁻⁵ ampere. The difference of current magnitudes may be sufficient to distinguish two states.

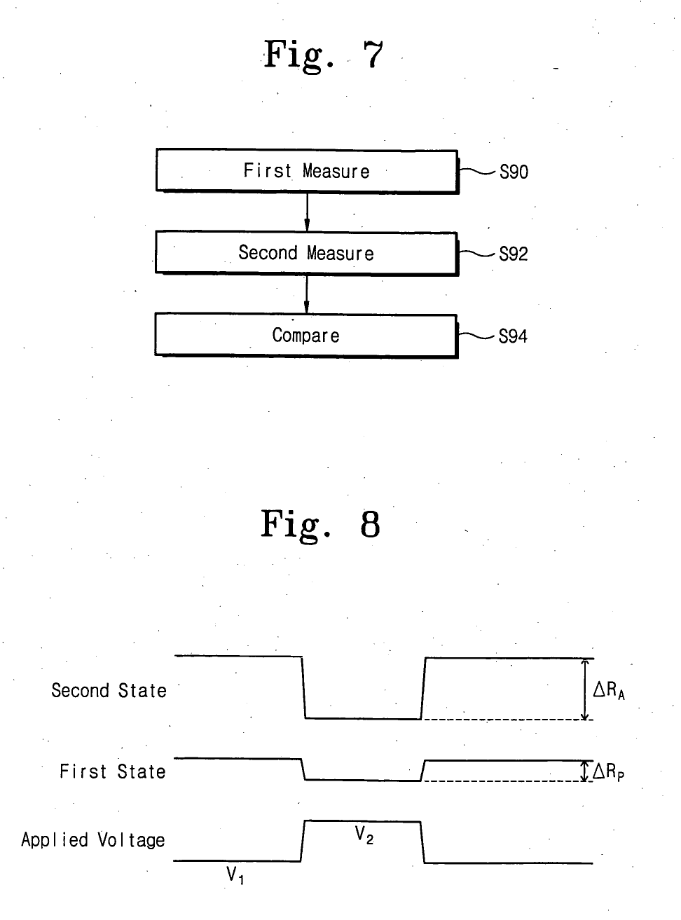

FIG. 4C illustrates a change of resistance. When a voltage applied to the data storage element 300 increases from 0.01 volt to 0.6 volt, a change of resistance may be about 800 ohms when data of the first-state data is stored, and a change of resistance may be about 1800 ohms when data of the second-state data is stored. Therefore, a difference of resistance magnitudes between the first-state data and the second-state data may be about 1000 ohms. The gap of the current change and/or the gap of the resistance change may be used to read the data stored in the data storage element 300 as discussed below with reference to FIG. 7 and FIG. 8.

A unit storage cell of a memory device according to embodiments of the invention will be discussed with reference to FIG. 5. The memory device has wordlines WL arranged in one direction and bitlines BL arranged perpendicular with respect to the wordlines WL, and data storage elements are provided at intersections of word and bit lines. A gate G of a storage cell transistor is connected to the wordline WL, and a data storage element 300 is connected to the bitline BL. The data storage element 300 has a first terminal 310 and a second terminal 320 as discussed above with reference to FIG. 2. In some embodiments of the present invention, the first terminal 310 of the data storage element 300 is connected to the bitline BL, and the second terminal 320 thereof is connected to a drain D of the storage cell transistor.

The bitline BL and the wordline WL are selected to select a desired storage cell of the memory cell array. Reading data stored in the data storage element 300 of the desired storage cell may include applying a voltage to the wordline WL to turn on the storage cell transistor, providing a potential difference between the bitline BL and a source S of the cell transistor, and sensing a current flowing through the selected bitline BL. A sensing circuit including a sense amplifier may be provided at the bitline BL to sense the current flowing through the bitline BL.

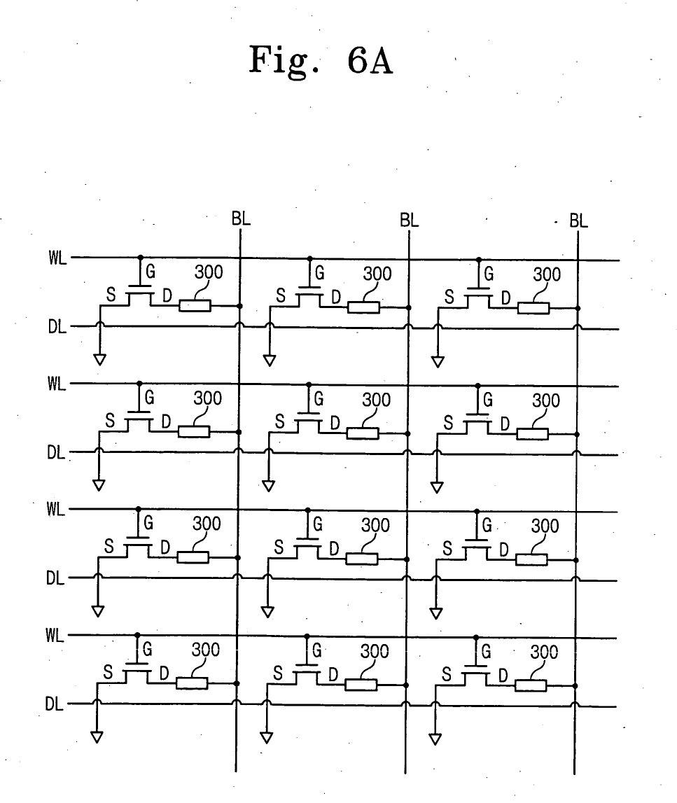

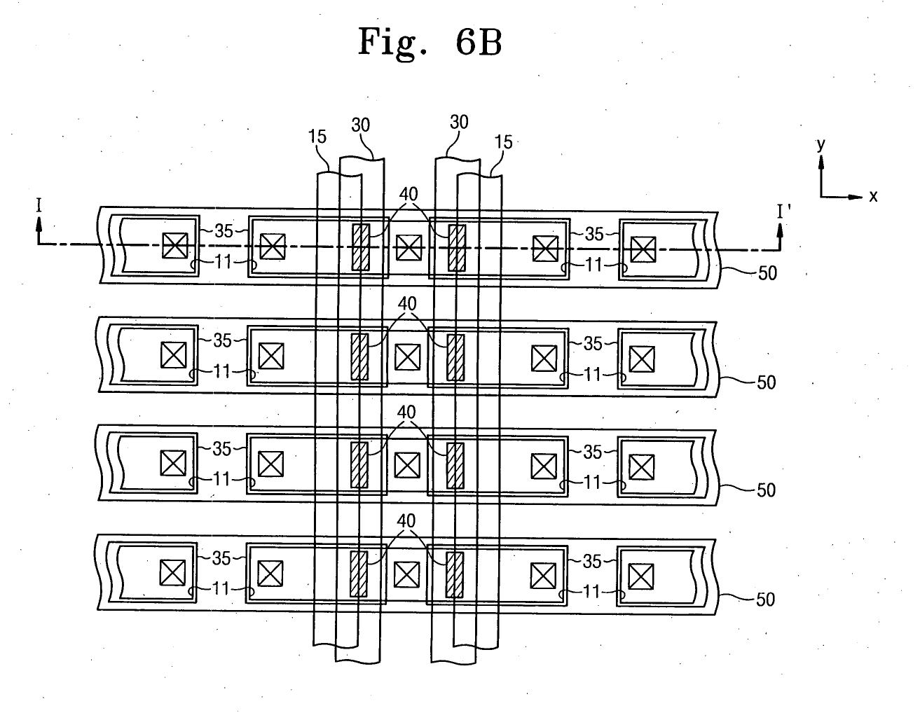

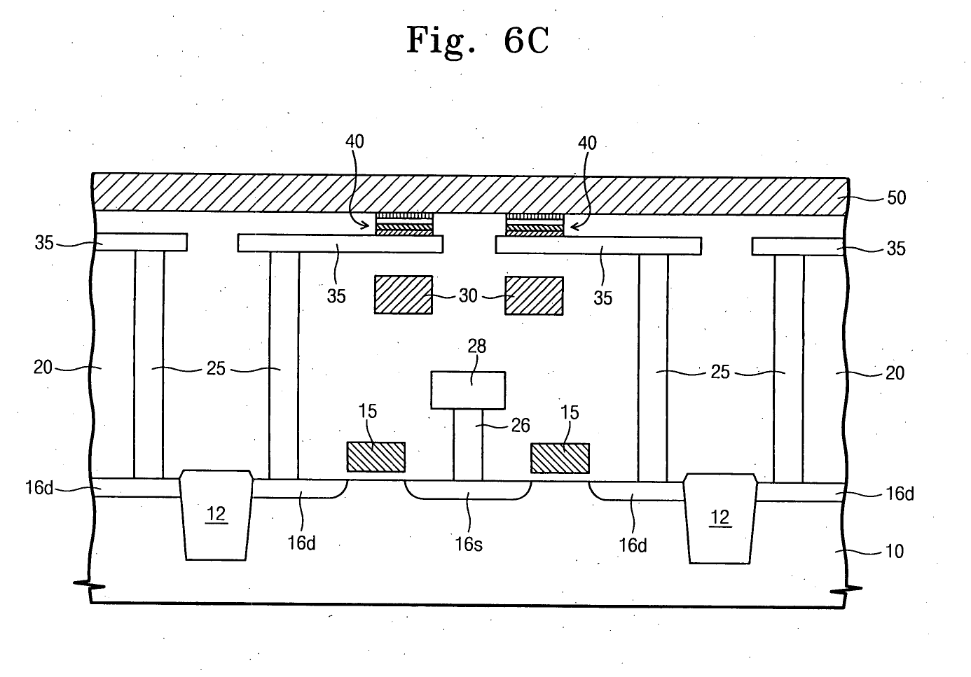

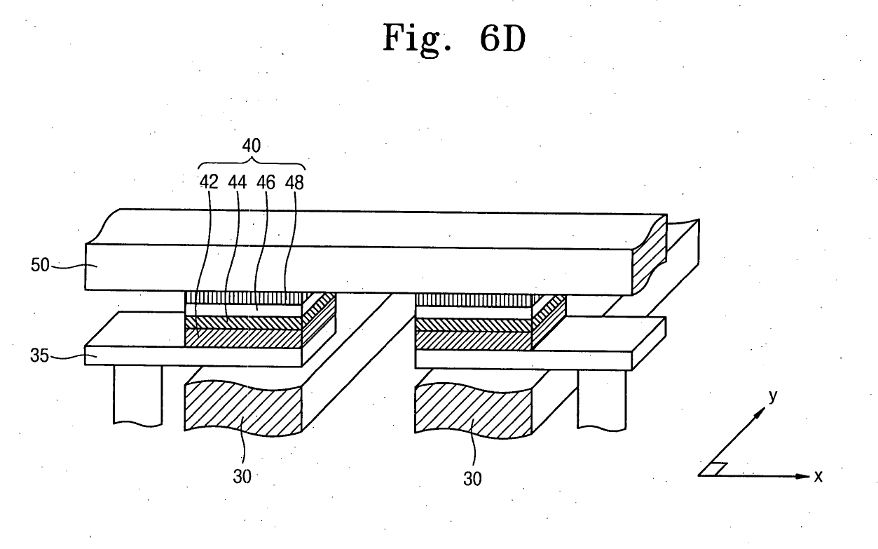

FIG. 6A, FIG. 6B, and FIG. 6C are respectively a circuit diagram, a top plan view, and a cross-sectional view of a portion of a data storage cell array region in the memory device according to embodiments of the present invention. More particularly, FIG. 6C is a cross-sectional view taken along section line I-I′ of FIG. 6B. FIG. 6D is a perspective view illustrating a configuration of a data storage element according to embodiments of the present invention.

Referring to FIG. 6A, a plurality of storage cell transistors may be arranged in a 2-dimensional array of rows and columns. Each of the cell transistors may be a MOSFET having a gate G, a source S, and a drain D formed on a semiconductor substrate. The storage cell transistors may be interconnected using a plurality of wordlines WL and/or bitlines BL. The wordlines WL and the bitlines BL are arranged in row and column directions and are respectively connected to the gates G of the cell transistors and the data storage elements 300. As discussed above, each data storage element 300 includes a magnetic tunnel junction (MTJ) structure data storage element between the respective bitline BL and cell transistor. The MTJ data storage may be used to store data in an MRAM.

A plurality of digit lines DL may be provided to cross the cell transistors. Each digit line DL may be provided in parallel with respect to the wordlines WL. Thus, the wordlines WL and the digit lines DL all cross the bitlines BL. When using a wordline WL, a bitline BL, and a digit line DL to select a cell transistor, cell transistors selected by the wordline WL and the digit line DL may be the same, because the wordline WL and the digit line DL are provided in the same direction. The bitline BL interconnects storage cells in a direction perpendicular with respect to the wordline WL and the digit line DL.

Referring to FIG. 6B, FIG. 6C, and FIG. 6D, device isolation layers 12 may be provided at regions of a semiconductor substrate 10 to define active regions 11 therebetween. A plurality of gate electrodes 15 (i.e., wordlines) may be provided on the semiconductor substrate including the device isolation layers 12 to cross the active regions 11 and the device isolation layers 12. A pair of gate electrodes 15 crosses each of active regions 11 perpendicularly. Assuming that lengthwise directions of the active regions 11 are provided in a row direction (x-axis direction), the gate electrodes 15 are arranged in a column direction (y-axis direction). A common source region 16s may be provided at an active region 11 between the gate electrodes 15, and drain regions 16d may be provided in an active region on opposite sides of the common source region 16s. Cell transistors may thus be formed at intersections of the active regions 11 and the gate electrodes 15 (i.e., wordlines).

An interlayer dielectric 20 is formed on an entire surface of the semiconductor substrate including the cell transistors (for example, using a plurality of insulating layers). A plurality of digit lines 30 may be provided in the interlayer dielectric 20 parallel with respect to the gate electrodes 15 (i.e., wordlines). A plurality of bitlines 50 may be provided on the interlayer dielectric 20 and the digit lines 30. The bitlines 50 may cross the gate electrodes 15 (i.e., wordlines), and the bitlines 50 may be parallel with respect to the active regions 11. A magnetic tunnel junction (MTJ) 40 (i.e. a data storage element) may be provided between a bitline 50 and a digit line 30. The MTJ 40 is one of the above-described data storage elements 300 according to embodiments of the present invention.

A lower electrode 35 is provided between the MTJ 40 and the digit line 30. The lower electrode 35 extends toward a respective drain region 16d. The MTJ 40 is connected between a top surface of the lower electrode 35 and a bottom surface of the bitline 50. A vertical interconnection 25 is provided through the interlayer dielectric 20 to electrically connect the lower electrode 35 and the drain region 16d. The vertical interconnection 25 may include a plurality of plug structures that are sequentially stacked. A source plug 26 and a source line 28 may be sequentially connected to a common source region 16s.

As previously stated, the MTJ 40 includes a pinning layer 42, a pinned layer 44, an insulation layer 46, and a free layer 48 that may be stacked in the order named. The pinning layer 42 may be an anti-ferromagnetic layer (including at least one selected from the group consisting of IrMn, PtMn, MnO, MnS, MnTe, MnF₂, FeF₂, FeCl₂, FeO, CoCl₂, CoO, NiCl₂, NiO, and/or Cr). The pinned layer 44 and the free layer 48 may be ferromagnetic layers (each including at least one selected from the group consisting of Fe, Co, Ni, Gd, Dy, MnAs, MnBi, MnSb, CrO₂, MnOFe₂O₃, FeOFe₂O₃, CuOFe₂O₃, MgOFe₂O₃, EuO, and/or Y₃Fe₅O₁₂). More particularly, the pinned layer 44 may be a triple layer with a ruthenium layer provided between two layers of the above-described ferromagnetic materials. The insulation layer 46 may be a layer of aluminum oxide. The MTJ 40 may be rectangular, such that its length is longer or shorter than its width.

A resistance of the MTJ 40 when the free layer 48 and the pinned layer 44 have the same magnetization direction (parallel) is lower than a resistance thereof when the free layer and the pinned layer have different magnetization directions (antiparallel). Further, a resistance change based on fluctuation of an applied voltage when their magnetization directions are antiparallel (see plot 200 of FIG. 2) may change more rapidly than a resistance change when their magnetization directions are parallel (see plot 100 of FIG. 2).

Unit cells of a magnetic memory device according to embodiments of the present invention may be arranged 2-dimensionally as well as 3-dimensionally. That is, there may be a plurality of planes, with each plane including a 2-dimensional array of memory cells of the magnetic memory device. Moreover, a magnetic memory device according to embodiments of the present invention may or may not have a semiconductor substrate with transistors formed therein. That is, a unit cell may be provided without a transistor. In this case, the magnetic layer may be connected to a functional circuit including transistors. The connection may be provided using wire bonding, flip-chip bonding, solder bumps, or other connection technologies known to those having skill in the art.

FIG. 7 is a flowchart illustrating a read operation of a memory device according to some embodiments of the present invention. FIG. 8 is a graph illustrating a resistance variation with fluctuation of a voltage applied to a data storage element for a read operation of a memory device according to some embodiments of the present invention.

Referring to FIG. 7, a first current I₁ flowing to the data storage element 300 is measured while applying a first voltage V₁ between the first and second terminals 310 and 320 of the data storage element 300 at block S90. In embodiments where the MTJ 40 is used as the data storage element 300, the current may be a tunneling current flowing through the insulation layer 46 between the free layer 48 and the pinned layer 44.

A second current I₂ flowing through the data storage element 300 is measured while applying a second voltage V₂, which is different from the first voltage V₁, between the first and second terminals 310 and 320 at block S92. A difference between the first and second currents I₁ and I₂ is compared with a predetermined reference value at block S94. The first and second voltages V₁ and V₂ may have magnitudes sufficiently low so as not to change data stored in the data storage element 300. According to some embodiments of the present invention, the first voltage V₁ may be in the range of about 0.01 volts to about 0.2 volts, and the second voltage V₂ may be in the range of about 0.3 volts to about 2.0 volts.

Referring to FIG. 7 and FIG. 8, when the second voltage V₂ is applied, a resistance between the first and second terminals 310 and 320 may be reduced further than when the first voltage V₁ is applied. In this case, a change of the resistance may vary with data stored in the data storage element 300. In the embodiment where the MTJ 40 is used as the data storage element 300, a resistance change ΔR_{A} measured when the free layer 48 and the pinned layer 44 have antiparallel magnetization directions is greater than a resistance change ΔR_{P} measured when the free layer and the pinned layer they have parallel magnetization directions. Thus, a measured resistance change ΔR is compared with a predetermined reference change ΔR₀ (e.g., a threshold change rage) to determine a state of data stored in the data storage element 300. Such a comparison may be done at block S94.

As discussed above, because a read operation includes applying a relatively low voltage to a data storage element to determine data stored in the data storage element, the stored data may remain unchanged during the read operation. Thus, a write operation used to restore initial data stored in the data storage element may not be needed during the read operation, and power consumption of a semiconductor device may be reduced. Read operations for magnetic memory devices according to embodiments of the present invention may be used for low-power-consumption semiconductor devices because a write operation may be avoided after a read operation.

Further, the stored data is determined using a current or resistance change measured at different voltages as opposed to a physical quantity measured at a predetermined voltage as in an external reference scheme. When using such a change characteristic varying with stored data, a read operation may be performed without distributional characteristic problems caused by changes of a fabricating process.

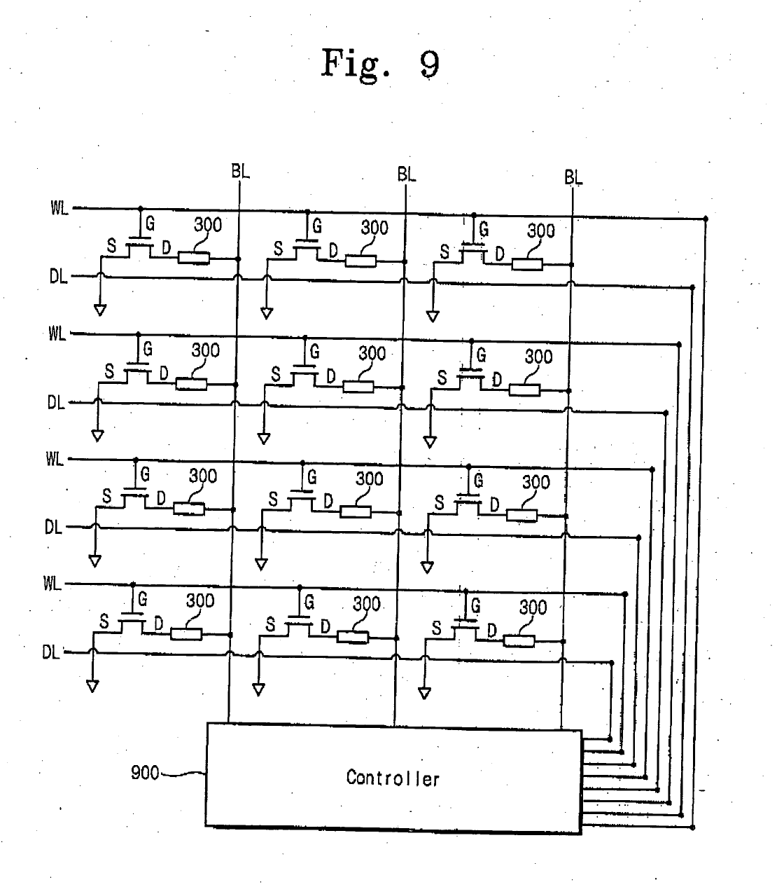

FIG. 9 is a circuit diagram illustrating the two-dimensional memory array of FIG. 6A with a controller 900 separately coupled to the wordlines WL, bitlines BL, and digitlines DL. Accordingly, the controller 900 may separately control signals applied to the respective wordlines WL, bitlines BL, and digitlines DL. The bitlines BL, wordlines WL, data storage elements 300, digitlines DL, and transistors (including gates G, sources S, and drains D) are the same as discussed above with respect to FIG. 6A.

When reading data from a particular data storage element, the controller 900 may be configured to apply signals to the wordline WL and the bitline BL associated with the data storage element according to the operations and/or signals illustrated in FIGS. 7 and/or 8. More particularly, the controller 900 may be configured to take a first measurement of an electrical characteristic of the data storage element while applying a first electrical signal to the data storage element, and to take a second measurement of the electrical characteristic of the data storage element while applying a second electrical signal to the data storage element after taking the first measurement. The controller 900 may then compare the first and second measurements of the electrical characteristic of the data storage element to determine a state of the data stored in the data storage element. More particularly, the controller 900 may apply a read select signal to the wordline WL associated with the data storage element to thereby turn on the transistor coupled to the data storage element while applying the first and second electrical signals to the bitline BL coupled to the data storage element.

While the present invention has been particularly shown and described with reference to embodiments thereof, it will be understood by those skilled in the art that various changes in form and details may be made therein without departing from the spirit and scope of the invention as defined by the appended claims and their equivalents.

What is claimed is:

1. A method of reading data stored in a data storage element of an integrated circuit memory device, the method comprising:
applying a first electrical signal to the data storage element;
while applying the first electrical signal, taking a first measurement of an electrical characteristic of the data storage element;
after taking the first measurement of the electrical characteristic, applying a second electrical signal to the data storage element wherein the first and second electrical signals are different;
while applying the second electrical signal, taking a second measurement of the electrical characteristic of the data storage element; and
comparing the first and second measurements of the electrical characteristic of the data storage element to determine a state of the data stored in the data storage element.

2. A method according to claim 1 wherein the data storage element comprises a magnetic tunnel junction (MTJ) structure.

3. A method according to claim 2 wherein the magnetic tunnel junction structure comprises a pinning layer, a pinned layer, an insulation layer, and a free layer, wherein the pinned layer is between the pinning layer and the insulation layer, and wherein the insulation layer is between the pinned layer and the free layer.

4. A method according to claim 3 wherein the pinning layer comprise an anti-ferromagnetic layer.

5. A method according to claim 3 wherein the pinned layer and the free layer each comprise a respective ferromagnetic layer.

6. A method according to claim 3 wherein the insulation layer comprises an aluminum oxide layer.

7. A method according to claim 1 wherein applying the first electrical signal comprises applying a first voltage across the data storage element, wherein applying the second electrical signal comprises applying a second voltage across the data storage element, and wherein the first and second voltages are different.

8. A method according to claim 7 wherein taking the first measurement of the electrical characteristic comprises measuring a first current through the data storage element, and wherein taking the second measurement of the electrical characteristic comprises measuring a second current through the data storage element.

9. A method according to claim 7 wherein taking the first measurement of the electrical characteristic comprises measuring a first resistance through the data storage element, and wherein taking the second measurement of the electrical characteristic comprises measuring a second resistance through the data storage element.

10. A method according to claim 1 wherein data stored in the data storage element takes one of first and second data states, wherein a difference between the first and second measurements is below a threshold when data of the first data state is stored in the data storage element, and wherein the difference between the first and second measurements exceeds the threshold when data of the second data state is stored in the data storage element.

11. An integrated circuit memory device comprising:
a data storage element; and
a controller coupled to the data storage element, the controller being configured to take a first measurement of an electrical characteristic of the data storage element while applying a first electrical signal to the data storage element, to take a second measurement of the electrical characteristic of the data storage element while applying a second electrical signal to the data storage element after taking the first measurement, and to compare the first and second measurements of the electrical characteristic of the data storage element to determine a state of the data stored in the data storage element.

12. An integrated circuit memory device according to claim 11 wherein the data storage element comprises a magnetic tunnel junction (MTJ) structure.

13. An integrated circuit memory device according to claim 12 wherein the magnetic tunnel junction structure comprises a pinning layer, a pinned layer, an insulation layer, and a free layer, wherein the pinned layer is between the pinning layer and the insulation layer, and wherein the insulation layer is between the pinned layer and the free layer.

14. An integrated circuit memory device according to claim 13 wherein the pinning layer comprise an anti-ferromagnetic layer.

15. An integrated circuit memory device according to claim 13 wherein the pinned layer and the free layer each comprise a respective ferromagnetic layer.

16. An integrated circuit memory device according to claim 13 wherein the insulation layer comprises an aluminum oxide layer.

17. An integrated circuit memory device according to claim 11 wherein the controller is configured to apply the first electrical signal by applying a first voltage across the data storage element, wherein the controller is configured to apply the second electrical signal by applying a second voltage across the data storage element, and wherein the first and second voltages are different.

18. An integrated circuit memory device according to claim 17 wherein the controller is configured to take the first measurement of the electrical characteristic by measuring a first current through the data storage element, and wherein the controller is configured to take the second measurement of the electrical characteristic by measuring a second current through the data storage element.

19. An integrated circuit memory device according to claim 17 wherein the controller is configured to take the first measurement of the electrical characteristic by measuring a first resistance through the data storage element, and wherein the controller is configured to take the second measurement of the electrical characteristic by measuring a second resistance through the data storage element.

20. An integrated circuit memory device according to claim 11 wherein data stored in the data storage element takes one of first and second data states, wherein a difference between the first and second measurements is below a threshold when data of the first data state is stored in the data storage element, and wherein the difference between the first and second measurements exceeds the threshold when data of the second data state is stored in the data storage element.
